(19) United States
(12) Patent Application Publication
(10) Pub. No.: US 2003/0143813 A1
(43) Pub. Date: Jul. 31, 2003

(54) Semiconductor device and method

(75) Inventors: Rajesh B. Khamankar, Coppell, TX (US); Amitabh Jain, Richardson, TX (US); Che-Jen Hu, Plano, TX (US); Mark S. Rodder, University Park, TX (US); Sunil V. Hattangady, McKinney, TX (US); Hiroaki Niimi, Richardson, TX (US); Zhiqiang Wu, Plano, TX (US); Manoj Mehrotra, Plano, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/140,715

(22) Filed: May 7, 2002

Related U.S. Application Data
(60) Provisional application No. 60/353,456, filed on Jan. 31, 2002.

(51) Int. Cl. H01L 21/336

(52) U.S. Cl. 438/299

(57) ABSTRACT

A semiconductor device and method for reducing dopant loss includes forming a gate electrode of an MOS transistor adjacent a semiconductor substrate. A relatively thin oxide screen layer is formed and disposed outwardly from the gate electrode. Nitrogen is then incorporated into the oxide screen layer. An upper dielectric layer is formed such that it is disposed outwardly from the nitrided oxide screen layer.

### RELATED APPLICATION

This Application claims the priority under 35 U.S.C. §119 of provisional application Ser. No. 60/353,456, entitled “Semiconductor Device and Method,” filed Jan. 31, 2002.

### TECHNICAL FIELD OF THE INVENTION

This invention relates generally to techniques for fabricating semiconductor devices and, more specifically, to reducing dopant loss.

### BACKGROUND OF THE INVENTION

Dopant loss from a semiconductor layer to an oxide layer is a problem that occurs during semiconductor fabrication. Loss of dopant can have a detrimental effect on a number of semiconductor device properties including poly depletion due to dopant loss from the polysilicon gate, a source-drain resistance increase due to dopant loss from the source-drain extension region, and others. The dopant loss into the oxide layer can be aggravated by various steps in the fabrication process.

### SUMMARY OF THE INVENTION

One aspect of the invention is a method for reducing dopant loss includes forming a gate electrode of an MOS transistor adjacent a semiconductor substrate. A relatively thin oxide screen layer is formed and disposed outwardly from the gate electrode. Nitrogen is then incorporated into the oxide screen layer. An upper dielectric layer is formed such that it is disposed outwardly from the nitrided oxide screen layer.

The invention has several important technical advantages. Various embodiments of the invention may have none, one, some or all of these advantages. The invention further expands the options for device design and manufacturing by better controlling dopant loss. Reducing dopant loss also may allow maintenance of the desired device properties. Other technical advantages of the present invention will be readily apparent to one skilled in the art.

### BRIEF DESCRIPTION OF THE DRAWINGS

For a more complete understanding of the present invention and its advantages, reference is now made to the following descriptions, taken in conjunction with the accompanying drawings, in which:

FIG. 1 is a cross-sectional view illustrating a portion of an embodiment of a semiconductor device constructed in accordance with the present invention;

FIGS. 2a-f are cross-sectional views illustrating a first example method of forming the semiconductor device of FIG. 1; and

FIGS. 3a-e are cross-sectional views illustrating a second example method of forming the semiconductor device of FIG. 1.

### DETAILED DESCRIPTION OF THE INVENTION

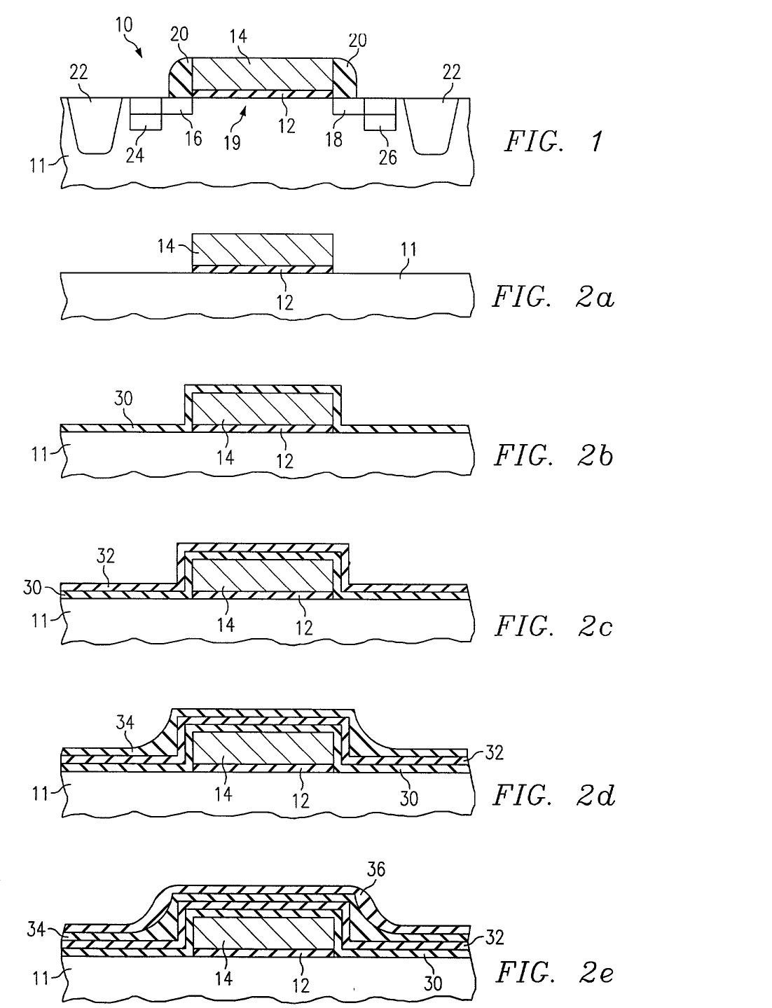

FIG. 1 illustrates a cross-sectional view of a semiconductor device 10 manufactured in accordance with the present invention. Semiconductor device 10 comprises an MOS transistor. Particular examples and dimensions specified throughout this document are intended for exemplary purposes only and are not intended to limit the scope of the invention unless expressly included in the claims.

Semiconductor device 10 includes a semiconductor substrate 11 and a gate dielectric 12 with a gate electrode 14 covering substantially all of the gate dielectric 12. Semiconductor device 10 further includes source extension 16 and drain extension 18 that extend partially under gate dielectric layer 12 and are separated by a channel region 19. Semiconductor device 10 also includes source region 24 and drain region 26 that may (but do not have to) extend at least partially under spacers 20, respectively.

Gate dielectric layer 12 is disposed adjacent to semiconductor substrate 11 and serves to insulate gate electrode 14 from semiconductor substrate 11. Gate dielectric layer 12 may be formed on part of semiconductor substrate 11 by any of a variety of techniques known to those skilled in the art. Gate dielectric layer 12 could comprise sublayers without departing from the scope of the invention. Disposed on gate dielectric layer 12 is gate electrode 14. Gate electrode 14 may be formed on gate dielectric layer 12 by any known technique.

Source extension 16 and drain extension 18 are formed within semiconductor substrate 11. In this embodiment, source extension 16 and drain extension 18 extend at least partially under gate dielectric layer 12 and are separated by substantially undoped channel region 19 of semiconductor substrate 11.

Source extension 16 and drain extension 18 are formed by doping those particular regions of semiconductor substrate 11. Doping may be accomplished by ion implantation, diffusion or any other suitable process. Source extension 16 and drain extension 18 may be either N-type or P-type.

It will be understood that source extension 16 and drain extension 18 may be interchangeable with each other. Thus, source extension 16 may behave as a drain extension and drain extension 18 may behave as a source extension. In other embodiments, however, source extension 16 and drain extension 18 are not interchangeable.

Isolation structures 22 can be formed using any type of isolation, such as, for example, local oxidation on silicon (“LOCOS”), shallow trench isolation, and other technologies. Semiconductor device 10 also includes source region 24 and drain region 26. The formation of source region 24 and drain region 26 is substantially similar to the formation of source extension 16 and drain extension 18; however, when forming source region 24 and drain region 26 the dopant may penetrate further into semiconductor substrate 11. As with source extension 16 and drain extension 18, in the present embodiment source region 24 and drain region 26 may be interchangeable with each other. Thus, source region 24 may behave as a drain region and drain region 26 may behave as a source region. In other embodiments, however, source region 24 and drain region 26 are not interchangeable.

In one embodiment of the present invention, spacers 20 include two layers. The first layer, disposed on the substrate and proximate the gate, is a relatively thin oxide screen layer that was subjected to a nitridation process. The nitridation process may be plasma nitridation, thermal nitridation, or any other nitriding process that implants a nitriding ambient in the oxide screen layer and substantially reduces dopant loss from semiconductor device 10. The second layer, disposed outwardly from the oxide screen layer, is an upper dielectric layer, such as an upper oxide layer.

In an alternative embodiment, spacers 20 includes three layers. The first layer, disposed on the substrate and proximate the gate, is a relatively thin oxide screen layer. The second layer is a first nitride layer that is approximately 40 angstroms thick. The nitride layer substantially reduces dopant loss into upper layers. The third layer, disposed outwardly from the first nitride layer, is an upper dielectric layer, such as an upper oxide layer.

In one embodiment, the source region 24 and drain region 26 are implanted with dopants. The dopants diffuse from the semiconductor substrate 11 to outward oxide layers generally during a cleaning, transient diffusion, or a thermal process, such as annealing. The amount of dopant loss is related to the thickness of the oxide layers. Nitrogen, nitride, or any nitriding ambient substantially reduces dopant loss by separating the dopant implanted region and the upper oxide layers and substantially preventing dopants from travelling from the semiconductor substrate 11 to the upper oxide layers.

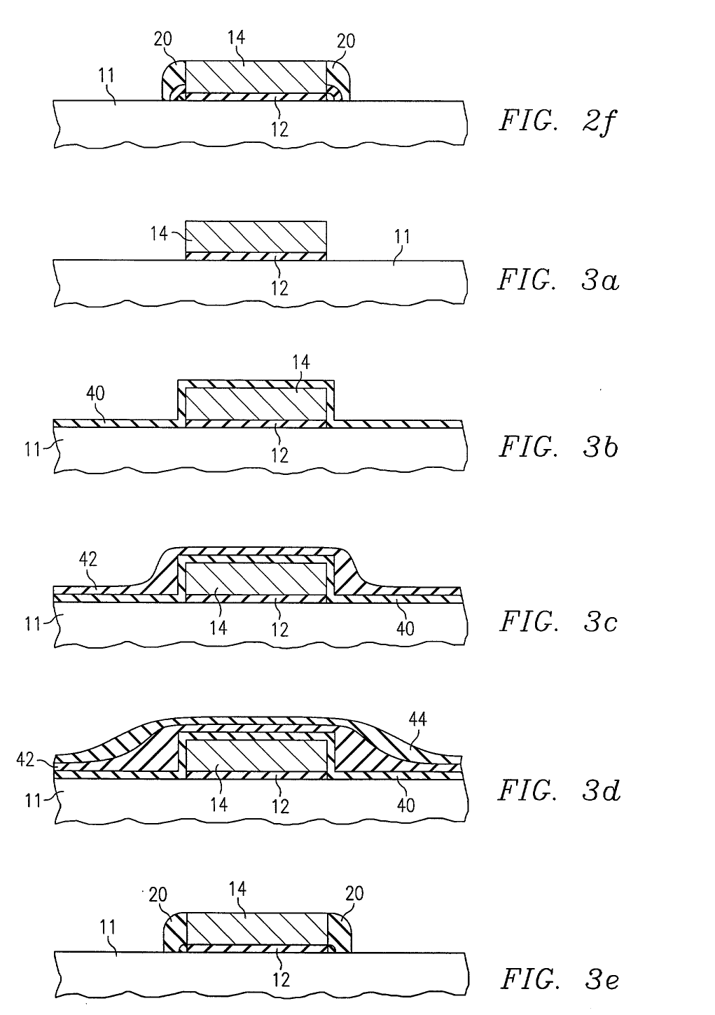

FIGS. 2a through 2f are cross-sectional views illustrating one embodiment of a method of forming semiconductor device 10.

Referring now to FIG. 2a, a gate has been formed on semiconductor substrate 11. Gate electrode 14 is separated from semiconductor substrate 11 by gate dielectric 12.

In FIG. 2b, an oxide screen layer 30 is disposed outwardly from the gate. In this embodiment, the oxide screen layer 30 is relatively thin (approximately 20 angstroms thick) and is formed from a single polyoxide material. The oxide screen layer 30 may comprise other materials or may comprise a plurality of layers without departing from the scope of the present invention. It may also be of a different thickness. Other embodiments of the present invention may exclude oxide screen layer 30 or may include a plurality of layers comprising or in place of oxide screen layer 30.

In FIG. 2c, a nitride layer 32 is disposed outwardly from the oxide screen layer 30. In this embodiment, nitride layer 32 is approximately between 20 and 80 angstroms thick. While desirable results may be obtained with this thickness range, the invention is not limited to any particular thickness unless expressly included in the claims. The nitride layer 32 may be silicon nitride that is conformably deposited on oxide screen layer 30. Nitride layer 32 may be formed by any technique, such as, for example, chemical vapor deposition, and may comprise any nitride. Nitride layer 32 may substantially reduce dopant loss from semiconductor device 10 by separating the dopant implanted semiconductor substrate 11 from the upper layers as described in FIG. 1.

In FIG. 2d, an upper oxide layer 34 is disposed outwardly from the nitride layer 32. In this embodiment, the upper oxide layer 34 is between 100 and 200 angstroms thick. While desirable results may be obtained with this thickness range, the invention is not limited to any particular thickness unless expressly included in the claims. Upper oxide layer 34 may comprise a plurality of layers without departing from the scope of the present invention. Upper oxide layer 34 may comprise any oxide deposited by any technique. Various embodiments of the present invention may exclude upper oxide layer 34.

In FIG. 2e, an upper nitride layer 36 is disposed outwardly from upper oxide layer 34. The upper nitride layer 36 may be silicon nitride that is conformably deposited upon upper oxide layer 34. In this embodiment, the upper nitride layer 36 is between 500 and 800 angstroms thick. While desirable results may be obtained with this thickness range, the invention is not limited to any particular thickness unless expressly included in the claims. Upper nitride layer 36 may comprise other materials without departing from the scope of the present invention. Upper nitride layer 36 may be formed by any technique, such as, for example, chemical vapor deposition, and may comprise any nitride. Other embodiments of the present invention may exclude upper nitride layer 36 or may include one or more layers comprising other materials in place of upper nitride layer 36.

In FIG. 2f, various layers have been etched to form spacers 20. The upper nitride layer 36 layer is anisotropically etched until the outer surface of gate electrode 14 is exposed leaving spacers 20 disposed on opposite sidewalls of the gate electrode 14 and gate dielectric layer 12. Any etching technique or etchant may be used for the etching step.

FIGS. 3a through 3e are cross-sectional views illustrating one embodiment of an alternative method of forming semiconductor device 10.

Referring now to FIG. 3a, a gate has been formed on semiconductor substrate 11. Gate electrode 14 is separated from semiconductor substrate 11 by gate dielectric 12.

In FIG. 3b, an oxide screen layer 40 is disposed outwardly from the gate formed on semiconductor substrate 11. In this embodiment, the oxide screen layer 40 is formed from a single oxide material and is 20 to 80 angstroms thick. While desirable results may be obtained with this thickness range, the invention is not limited to any particular thickness unless expressly included in the claims. When the oxide screen layer 40 is between 40 to 53 angstroms thick and is subjected to nitridation favorable results have been obtained. The nitridation may be plasma nitridation, thermal nitridation using an oxynitride, or any other nitriding process that incorporates nitride into the oxide screen layer and substantially reduces dopant loss from semiconductor device 10. Dopant loss generally occurs during a cleaning, transient diffusion, or a thermal process, such as annealing. The nitrided oxide screen layer may substantially reduce dopant loss from semiconductor device 10 by separating the dopant implanted semiconductor substrate 11 from the upper layers as described in FIG. 1.

Oxide screen layer 40 may comprise other suitable materials or layers without departing from the scope of the present invention. Oxide screen layer 40 may be formed by any of a variety of techniques well known to those skilled in the art and may comprise any suitable oxide. Other embodiments of the present invention may use any suitable oxide that is capable of being nitrided, resulting in substantially reduced dopant loss from semiconductor device 10.

In FIG. 3c, an upper oxide layer 42 is disposed outwardly from the nitrided oxide screen layer 40. In this embodiment, the upper oxide layer 42 is 100 to 200 angstroms thick. While desirable results may be obtained with this thickness range, the invention is not limited to any particular thickness unless expressly included in the claims. Upper oxide layer 42 may comprise a plurality of layers without departing from the scope of the present invention. Upper oxide layer 42 may comprise any oxide deposited by any technique. Various embodiments of the present invention may exclude upper oxide layer 42.

In FIG. 3d, a nitride layer 44 is disposed outwardly from the upper oxide layer 42 using some form of conformal deposition. In this embodiment, the nitride layer 44 is 500 to 800 angstroms thick. While desirable results may be obtained with this thickness range, the invention is not limited to any particular thickness unless expressly included in the claims. Nitride layer 44 may comprise other materials without departing from the scope of the present invention. Nitride layer 44 may be formed by any technique, such as, for example, chemical vapor deposition, and may comprise any nitride. Other embodiments of the present invention may exclude nitride layer 44 or may include one or more layers comprising other materials in place of nitride layer 44.

FIG. 3f includes spacers 20 that are formed from etching the semiconductor device 20. The nitride layer 44 layer is anisotropically etched until the outer surface of gate electrode 14 is exposed leaving spacers 20 disposed on opposite sidewalls of the gate electrode 14 and gate dielectric layer 12. It will be understood that any suitable etching technique or etchant may be used.

Although the present invention has been described in detail, it should be understood that various changes, substitutions and alterations can be made hereto without departing from the sphere and scope of the invention as defined by the appended claims.

To aid the Patent Office, and any readers of any patent issued on this application in interpreting the claims appended hereto, applicants wish to note that they do not intend any of the appended claims to invoke ¶ 6 of 35 U.S.C. § 112 as it exists on the date of filing hereof unless “means for” or “step for” are used in the particular claim.

What is claimed is:

1. A method for manufacturing a semiconductor device, comprising:
forming a gate electrode of an MOS transistor adjacent a semiconductor substrate;
forming a relatively thin oxide screen layer disposed outwardly from the gate electrode; and
forming a first nitride layer on the oxide screen layer.

2. The method of claim 1 further comprising:
forming an upper oxide layer disposed outwardly from the first nitride layer; and
forming an upper nitride layer disposed outwardly from the upper oxide layer.

3. The method of claim 1, wherein the thickness of the oxide screen layer is between 20 and 50 angstroms.

4. The method of claim 1, wherein the thickness of the first nitride layer is between 20 and 60 angstroms.

5. The method of claim 2 further comprising etching the upper nitride, upper oxide, first nitride, and oxide screen layers to form one or more spacer structures proximate the gate.

6. A method for manufacturing a semiconductor device, comprising:
forming a gate electrode of an MOS transistor adjacent a semiconductor substrate;
forming a relatively thin oxide screen layer disposed outwardly from the gate electrode;
incorporating nitrogen into the oxide screen layer; and
forming an upper dielectric layer disposed outwardly from the nitrided oxide screen layer.

7. The method of claim 6, wherein incorporating nitrogen into the oxide screen layer comprises performing plasma nitridation on the oxide screen layer.

8. The method of claim 6, wherein incorporating nitrogen into the oxide screen layer comprises performing thermal nitridation on the oxide screen layer.

9. The method of claim 6, wherein the thickness of the oxide screen layer is between 20 and 80 angstroms.

10. The method of claim 6 further comprising forming a nitride layer disposed outwardly from the upper dielectric layer.

11. The method of claim 10 further comprising etching the nitride, upper dielectric, and oxide screen layers to form one or more spacer structures proximate the gate.

12. The method of claim 6, wherein the amount of nitrogen incorporated into the oxide screen layer is sufficient to substantially reduce diffusion of dopants out of a source extension region and drain extension region of the MOS transistor into the upper dielectric layer.

13. A semiconductor device, comprising:
a semiconductor substrate;
a gate of an MOS transistor adjacent the semiconductor substrate; and
one or more spacer structures proximate the gate,
wherein a spacer structure comprise:
a relatively thin nitrided oxide screen layer disposed outwardly from the gate; and
an upper dielectric layer disposed outwardly from the nitrided oxide screen layer.

14. The semiconductor device of claim 13, wherein the oxygen screen layer is nitrided through plasma nitridation.

15. The semiconductor device of claim 13, wherein the oxygen screen layer is nitrided through thermal nitridation.

16. The semiconductor device of claim 13, wherein the thickness of the oxide screen layer is between 20 and 80 angstroms.

17. The semiconductor device of claim 16, wherein the upper dielectric layer comprises an upper oxide layer and a nitride layer and the thickness of the upper oxide layer is between 100 and 200 angstroms and the thickness of the nitride layer is between 500 and 800 angstroms.

18. The semiconductor device of claim 13, wherein the amount of nitride in the nitrided oxide screen layer is sufficient to substantially reduce diffusion of dopants out of a source extension region and drain extension region of the MOS transistor into the upper dielectric layer.

19. A semiconductor device, comprising:
a semiconductor substrate;
a gate of an MOS transistor adjacent the semiconductor substrate; and
one or more spacer structures proximate the gate,
wherein a spacer structure comprises:
a relatively thin oxide screen layer disposed outwardly from the gate electrode; and
a first nitride layer on the oxide screen layer.

20. The semiconductor device of claim 19, wherein the thickness of the oxide screen layer is between 20 and 50 angstroms.

21. The semiconductor device of claim 19, wherein the thickness of the first nitride layer is between 20 and 60 angstroms.

22. The semiconductor device of claim 19, wherein the spacer structures further comprises an upper oxide layer disposed outwardly from the first nitride layer.

23. The semiconductor device of claim 22, wherein the thickness of the upper oxide layer is between 100 and 200 angstroms.

24. The semiconductor device of claim 22 further comprising a source extension region and a drain extension region.
